(19) United States
(12) Patent Application Publication
(10) Pub. No.: US 2026/0047200 A1
(43) Pub. Date: Feb. 12, 2026

(54) SEMICONDUCTOR DEVICE AND METHOD FOR FABRICATING THE SAME

(71) Applicant: Samsung Electronics Co., Ltd., Suwon-si (KR)

(72) Inventors: Sang Jin KIM, Suwon-si (KR); Yi Gwon KIM, Suwon-si (KR); Sung Gyu LEE, Suwon-si (KR); Ji Hun LEE, Suwon-si (KR)

(73) Assignee: Samsung Electronics Co., Ltd., Suwon-si (KR)

(21) Appl. No.: 19/097,947

(22) Filed: Apr. 2, 2025

(30) Foreign Application Priority Data
Aug. 6, 2024 (KR) 10-2024-0104855

(51) Int. Cl. H10D 84/90; H10D 89/10

(52) U.S. Cl. CPC H10D 84/929; H10D 84/953; H10D 89/10

(57) ABSTRACT

A semiconductor device includes a substrate, a first lower pattern on the substrate, and an element isolation film on the substrate and surrounding at least parts of sidewalls of the first lower pattern, wherein at least part of an upper surface of the first lower pattern is inclined relative to an upper surface of the substrate.

### CROSS-REFERENCE TO RELATED APPLICATION

This application claims priority from Korean Patent Application No. 10-2024-0104855 filed on Aug. 6, 2024, in the Korean Intellectual Property Office, and all the benefits accruing therefrom under 35 U.S.C. 119, the contents of which in its entirety are herein incorporated by reference.

### BACKGROUND

### 1. Field

The present disclosure relates to semiconductor devices and methods for fabricating the same, and more specifically, to semiconductor devices including a Multi-Bridge Channel Field Effect Transistor (MBCFET™) and methods for manufacturing the semiconductor device.

### 2. Description of the Related Art

As one of the scaling technologies to increase the density of semiconductor devices, a multi-gate transistor has been proposed, in which a fin or nanowire-shaped multi-channel active pattern (or silicon body) is formed on a substrate and a gate is formed on the surface of the multi-channel active pattern.

The multi-gate transistor utilizes a three-dimensional (3D) channel and is relatively easy to scale. Additionally, it is possible to enhance the current control capability of the multi-gate transistor even without increasing the gate length of the multi-gate transistor. Furthermore, the short channel effect (SCE), where the potential of the channel region is affected by the drain voltage, can be effectively suppressed.

### SUMMARY

Some example embodiments of the present disclosure provide semiconductor devices that can improve device performance and/or reliability.

Some example embodiments of the present disclosure also provide methods for manufacturing a semiconductor device that can improve device performance and/or reliability.

However, example embodiments of the present disclosure are not restricted to those set forth herein. The above and other aspects of the present disclosure will become more apparent to one of ordinary skill in the art to which the present disclosure pertains by referencing the detailed description of the present disclosure given below.

According to some example embodiments of the present disclosure, a semiconductor device includes a substrate, a first lower pattern on the substrate, and an element isolation film on the substrate and surrounding at least parts of sidewalls of the first lower pattern, wherein at least part of an upper surface of the first lower pattern is inclined relative to an upper surface of the substrate.

According to some example embodiments of the present disclosure, a semiconductor device includes a substrate including a logic cell region and a key region, a first lower pattern on the substrate, a second lower pattern on the substrate, a trench in the substrate between the first and second lower patterns, and an element isolation film filling the trench and surrounding at least parts of sidewalls of each of the first and second lower patterns, wherein the first and second lower patterns are in the key region or in a region including a transistor of a first conductivity type and within the logic cell region.

According to some example embodiments of the present disclosure, a method for fabricating a semiconductor device includes forming a first trench in a substrate, forming a stacked pattern on the substrate and along the first trench, the stacked pattern including a plurality of active layers and a plurality of sacrificial layers that are alternately stacked in a vertical direction, an upper surface of the stacked pattern including a recess overlapping the first trench in the vertical direction, forming a stopper film on the stacked pattern, forming a mask pattern including an opening on the stopper film, the opening overlapping the recess in the vertical direction, etching the stopper film, the stacked pattern, and the substrate using the mask pattern to remove the recess and to form a second trench, and forming an element isolation film filling the second trench.

It should be noted that the effects and advantages of the present disclosure are not limited to those described above, and other effects and advantages of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is a is a layout view for explaining a semiconductor device according to some example embodiments;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line D-D′ of FIG. 1;

FIGS. 6 through 14 are diagrams for explaining a method for fabricating a semiconductor device according to some example embodiments;

FIG. 15 is a diagram for explaining a semiconductor device according to some example embodiments;

FIG. 16 is a diagram for explaining a method for fabricating a semiconductor device according to some example embodiments;

FIG. 17 is a diagram for explaining a semiconductor device according to some example embodiments;

FIG. 18 is a diagram for explaining a method for fabricating a semiconductor device according to some example embodiments;

FIGS. 19 through 21 are diagrams for explaining a semiconductor device according to some example embodiments;

FIGS. 22 and 23 are diagrams for explaining a method for fabricating a semiconductor device according to some example embodiments;

FIGS. 24 through 26 are diagrams for explaining a method for fabricating a semiconductor device according to some example embodiments;

FIG. 27 is a diagram for explaining a semiconductor device according to some example embodiments;

FIG. 28 is a layout view for explaining the key region of FIG. 27;

FIGS. 29 through 31 are cross-sectional views taken along line G-G′ of FIG. 28;

FIG. 32 is a layout view for explaining the key region of FIG. 27;

FIGS. 33 and 34 are cross-sectional views taken along line H-H′ of FIG. 32;

FIG. 35 is a layout view for explaining the key region of FIG. 27;

FIG. 36 is a cross-sectional view taken along line I-I′ of FIG. 35; and

FIG. 37 is a diagram for explaining a method for fabricating a semiconductor device according to some example embodiments.

### DETAILED DESCRIPTION

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

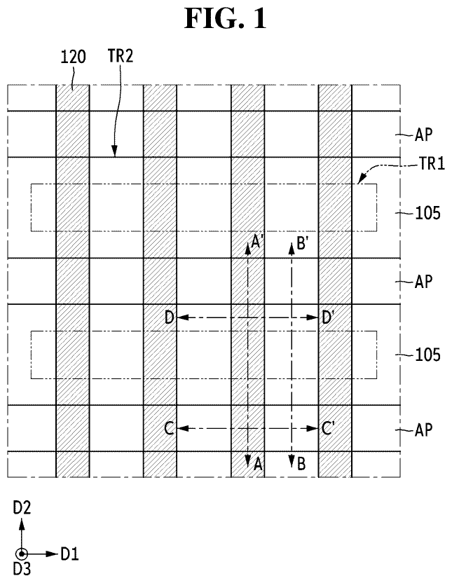

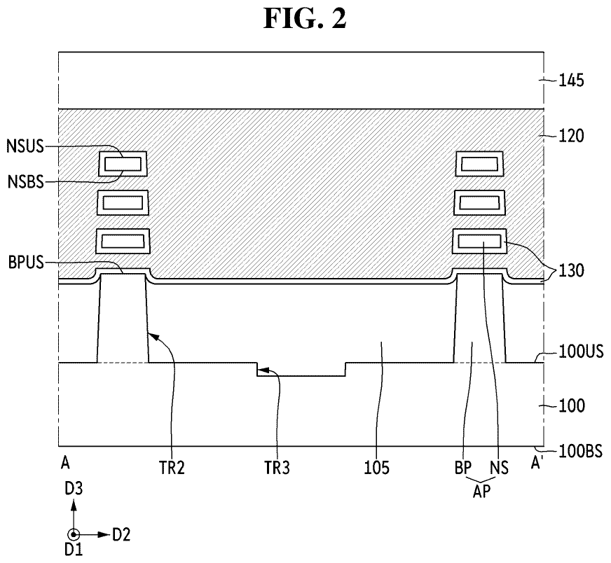

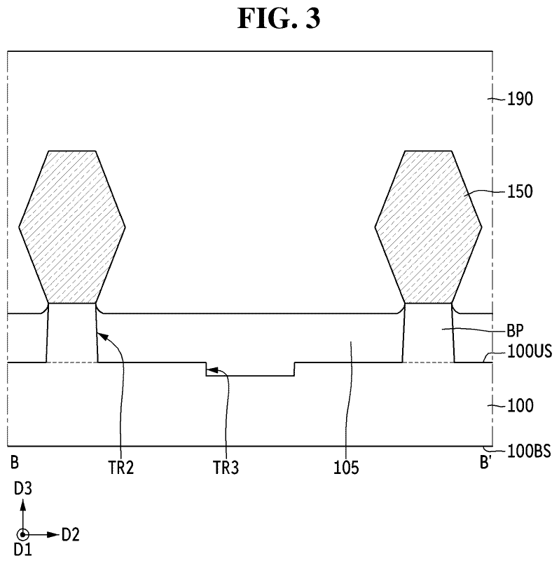

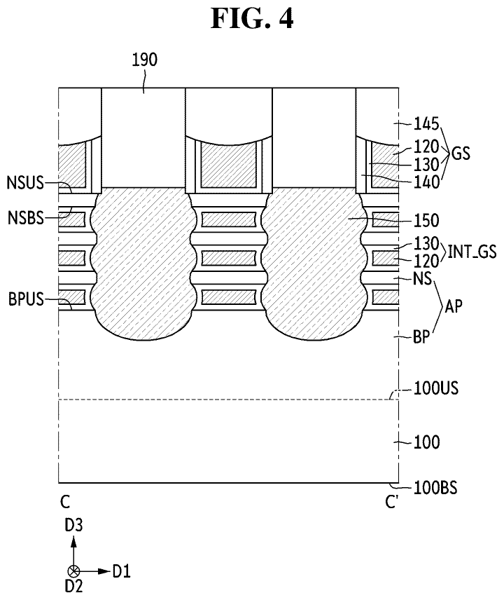

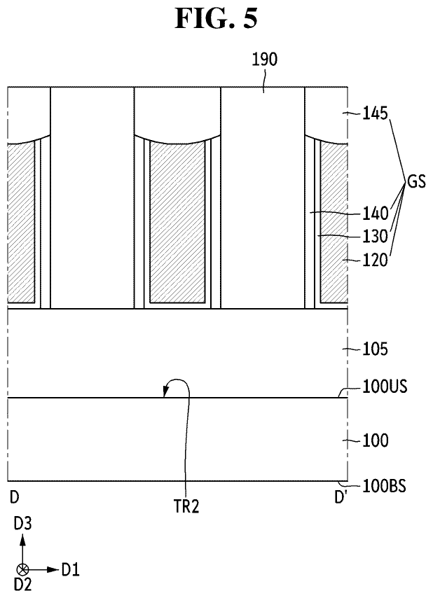

FIG. 1 is a layout view for explaining a semiconductor device according to some example embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line D-D′ of FIG. 1. For convenience, third trenches TR3 are omitted in FIG. 1.

Referring to FIGS. 1 through 5, the semiconductor device according to some example embodiments may include a substrate 100, an element isolation film 105, active patterns AP, a gate electrode 120, source/drain patterns 150, and an interlayer insulating film 190.

The substrate 100 may include an upper surface 100US and a lower surface 100BS that are opposite to each other in a third direction D3. A first direction D1 and a second direction D2 are directions that intersect each other and are parallel to the upper surface 100US, and the third direction D3 is a direction that intersects the first and second directions D1 and D2 and is perpendicular to the upper surface 100US.

The substrate 100 may include bulk silicon or silicon-on-insulator (SOI). In some example embodiments, the substrate 100 may be a silicon (Si) substrate or may include other materials, for example, silicon-germanium (SiGe), SiGe-on-insulator (SGOI), indium antimonide, a lead telluride compound, indium arsenide, indium phosphide, gallium arsenide, or gallium antimonide, but example embodiments are not limited thereto.

The active patterns AP may be disposed on the upper surface 100US of the substrate 100. The active patterns AP may extend in the first direction D1. The active patterns AP may be arranged in the second direction D2.

The active patterns AP may be multi-channel active patterns. The active patterns AP may each include a lower pattern BP and a plurality of sheet patterns NS.

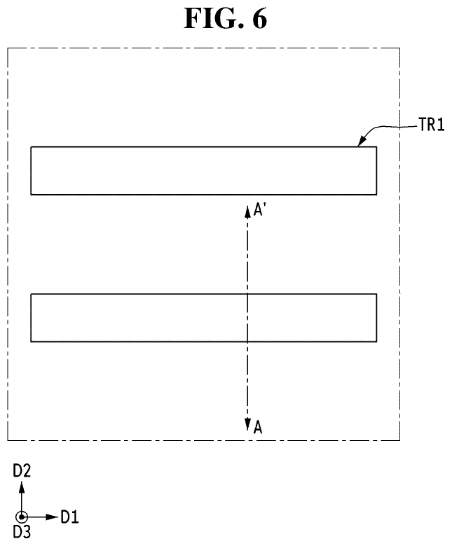

The lower patterns BP may protrude from the substrate 100. The lower patterns BP may protrude from the upper surface 100US of the substrate 100. The lower patterns BP may extend in the first direction D1. The lower patterns BP may be defined by second trenches TR2. The second trenches TR2 may extend in the first direction D1. The upper surface 100US of the substrate 100 may be defined by the second trenches TR2. The second trenches TR2 may be formed to be aligned with first trenches TR1. The second trenches TR2 may be formed in areas that overlap the first trenches TR1 in the third direction D3. The first trenches TR1 may be removed during the formation of the second trenches TR2. The first trenches TR1 will be described later in detail with reference to FIGS. 6 through 14.

The sheet patterns NS may be disposed on upper surfaces BPUS of the lower patterns BP. The sheet patterns NS may be spaced apart from the lower patterns BP in the third direction D3. The sheet patterns NS may be spaced apart from each other in the third direction D3. The sheet patterns NS may each have an upper surface NSUS and a lower surface NSBS that are opposite to each other in the third direction D3.

The lower patterns BP may be formed by etching parts of the substrate 100, or may each include an epitaxial layer grown from the substrate 100. The lower patterns BP may include Si or germanium (Ge), which is an elemental semiconductor material. In some example embodiments, the lower pattern BP may include a compound semiconductor, for example, a Group IV-IV compound semiconductor or Group III-V compound semiconductor. The Group IV-IV compound semiconductor may be, for example, a binary or ternary compound containing at least two elements from among carbon (C), Si, Ge, and tin (Sn), or a compound obtained by doping the binary or ternary compound with a Group IV element. The Group III-V compound semiconductor may be, for example, a binary, ternary, or quaternary compound formed by combining at least one Group III element from among aluminum (Al), gallium (Ga), and indium (In), with one Group V element from among phosphorus (P), arsenic (As), and antimony (Sb).

The sheet patterns NS may include Si or Ge, which is an elemental semiconductor material, a Group IV-IV compound semiconductor, and/or a Group III-V compound semiconductor. The sheet patterns NS may include the same material as the lower patterns BP, or may include a different material from the lower patterns BP.

In some example embodiments, the lower patterns BP and the sheet patterns NS may each include Si.

The width, in the second direction D2, of the sheet patterns NS in the second direction D2 may increase or decrease in proportion to the width, in the second direction D2, of the upper surfaces BPUS of the lower patterns BP. The widths, in the second direction D2, of the sheet patterns NS stacked in the third direction D3 may decrease away from the lower patterns BP. In some example embodiments, the width, in the second direction D2, of the sheet patterns NS stacked in the third direction D3 may be uniform.

In some example embodiments, the upper surfaces BPUS of the lower patterns BP, the upper surfaces NSUS of the sheet patterns NS, and the lower surfaces NSBS of the sheet patterns NS may be flat. From the perspective of a planar view that includes the second and third directions D2 and D3, the sheet patterns NS may have a linear shape extending in the second direction D2.

The element isolation film 105 may be formed on the substrate 100. The element isolation film 105 may be disposed on the sidewalls of the lower patterns BP. The element isolation film 105 may cover at least parts of the sidewalls of the lower patterns BP. The element isolation film 105 is not disposed on the upper surfaces BPUS of the lower patterns BP.

The element isolation film 105 may include, for example, an oxide film, a nitride film, an oxynitride film, or a combination thereof. The element isolation film 105 may be a single-layer film or a multi-layer film.

In some example embodiments, the upper surface 100US of the substrate 100 may have a step difference toward the lower surface 100BS of the substrate 100. The substrate 100 between adjacent active patterns AP may include the third trenches TR3. The third trenches TR3 may overlap the second trenches TR2. The third trenches TR3 may be recessed from the upper surface 100US of the substrate 100 toward the lower surface 100BS of the substrate 100. The bottom surfaces of the third trenches TR3 may be disposed lower than the bottom surfaces of the second trenches TR2. The third trenches TR3 may result from, for example, the first trenches TR1. The third trenches TR3 may be formed at positions corresponding to the first trenches TR1. The third trenches TR3 and the active patterns AP may extend in the first direction D1. The width of the third trenches TR3 in the first direction D1 may be smaller than the width of the active patterns AP in the first direction D1.

The active patterns AP adjacent to each other with the third trenches TR3 in between may be regions where transistors of the same conductivity type are formed. The element isolation film 105 may fill the third trenches TR3.

A plurality of gate structures GS may be disposed on the substrate 100. The gate structure GS may extend longitudinally in the second direction D2. The gate structures GS may be spaced apart from each other in the first direction D1.

The gate structures GS may be disposed on the active patterns AP. The gate structures GS may intersect the active patterns AP. The gate structures GS may intersect the lower patterns BP. The gate structures GS may surround the sheet patterns NS.

The gate structures GS may include, for example, gate electrodes 120, a gate insulating film 130, gate spacers 140, and gate capping patterns 145.

The gate structures GS may include a plurality of inner gate structures INT_GS, which are disposed between pairs of adjacent sheet patterns NS in the third direction D3, and between the lower patterns BP and the sheet patterns NS. The inner gate structures INT_GS may be disposed between the upper surfaces BPUS of the lower patterns BP and the lower surfaces NSBS of the lowermost sheet patterns NS, and between the upper surfaces NSUS and the lower surfaces NSBS of the sheet patterns NS that face each other in the third direction D3. The number of inner gate structures INT_GS may be the same as the number of sheet patterns NS. The inner gate structures INT_GS may contact the upper surfaces BPUS of the lower patterns BP, the upper surfaces NSUS of the sheet patterns NS, and the lower surfaces NSBS of the sheet patterns NS. The inner gate structures INT_GS may contact the source/drain patterns 150.

The inner gate structures INT_GS include the gate electrodes 120 and the gate insulating film 130, which is disposed between the pairs of adjacent sheet patterns NS and between the lower patterns BP and the sheet patterns NS.

The gate electrodes 120 may be disposed on the lower patterns BP. The gate electrodes 120 may intersect the lower patterns BP. The gate electrodes 120 may surround the sheet patterns NS. The upper surfaces of the gate electrodes 120 may be either concave surfaces or flat surfaces.

The gate electrodes 120 may include at least one of metal, a metal alloy, conductive metal nitride, metal silicide, a doped semiconductor material, conductive metal oxide, or conductive metal oxynitride. For example, the gate electrodes 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The conductive metal oxide and the conductive metal oxynitride may include oxidized forms of the aforementioned materials, but example embodiments are not limited thereto.

The gate insulating film 130 may extend along the upper surface of the element isolation film 105 and the upper surfaces BPUS of the lower patterns BP. The gate insulating film 130 may surround the sheet patterns NS. The gate insulating film 130 may be formed along the circumferences of the sheet patterns NS.

The gate insulating film 130 may include silicon oxide, silicon oxynitride, silicon nitride, or a high-k dielectric material with a greater dielectric constant than silicon oxide. The high-k dielectric material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The gate insulating film 130 may be a single-layer film or a multi-layer film. The gate insulating film 130 may also include an interfacial layer and a high-k dielectric insulating film disposed between the active patterns AP and the gate electrodes 120. For example, the interfacial layer may not be formed along the profile of the upper surface of the element isolation film 105.

The gate spacers 140 may be disposed on the sidewalls of the gate electrodes 120. The gate spacers 140 may not be disposed between the lower patterns BP and the sheet patterns NS, and between the pairs of adjacent sheet patterns NS in the third direction D3.

The gate spacers 140 may include at least one of silicon nitride (SiN), silicon oxynitride (SiON), silicon oxide (SiO₂), silicon oxycarbonitride (SiOCN), silicon boron nitride (SiBN), silicon oxynitride boron nitride (SiOBN), silicon oxycarbide (SiOC), or a combination thereof. The gate spacers 140 may be single-layer films or multi-layer films.

The gate capping patterns 145 may be disposed on the gate electrodes 120 and the gate spacers 140. The upper surfaces of the gate capping patterns 145 may be coplanar with the upper surface of the interlayer insulating film 190. In some example embodiments, contrary to what is illustrated, the gate capping patterns 145 may be disposed between the gate spacers 140.

The gate capping patterns 145 may include at least one of SiN, SiON, silicon carbonitride (SiCN), SiOCN, or a combination thereof. The gate capping patterns 145 may include a material with an etch selectivity relative to the interlayer insulating film 190.

The source/drain patterns 150 may be disposed on the active patterns AP. The source/drain patterns 150 may be disposed on the lower patterns BP. The source/drain patterns 150 are connected to the sheet patterns NS. The source/drain patterns 150 are in contact with the sheet patterns NS.

The source/drain patterns 150 may be disposed on the sides of the gate structures GS. The source/drain patterns 150 may be disposed between pairs of adjacent gate structures GS in the first direction D1. For example, the source/drain patterns 150 may be disposed on both sides of the gate structures GS, respectively. In some example embodiments, contrary to what is illustrated, the source/drain patterns 150 may be disposed on first sides of the gate structures GS and may not be disposed on second sides of the gate structures GS.

The source/drain patterns 150 may be the sources/drains of transistors that use the sheet patterns NS as channel regions.

The source/drain patterns 150 may include epitaxial patterns. The source/drain patterns 150 include a semiconductor material. For example, the source/drain patterns 150 may include an elemental semiconductor material such as Si or Ge. Additionally, the source/drain patterns 150 may include a binary or ternary compound containing at least two elements from among C, Si, Ge, and Sn, or a compound obtained by doping the binary or ternary compound with a Group IV element. For example, the source/drain patterns 150 may include Si, SiGe, or silicon carbide, but example embodiments are not limited thereto. The source/drain patterns 150 may be a single-layer film or a multi-layer film.

The source/drain patterns 150 may include impurities doped into a semiconductor material. In one example, the source/drain patterns 150 may include n-type impurities. The doped impurities may include at least one of P, As, Sb, or bismuth (Bi). In another example, the source/drain patterns 150 may include p-type impurities. The doped impurities may include boron (B). Each pair of adjacent source/drain patterns 150 with a third trench TR3 in between may include impurities of the same conductivity type.

The interlayer insulating film 190 may be disposed on the source/drain patterns 150. The interlayer insulating film 190 may be disposed on the sidewalls of the gate structures GS. The interlayer insulating film 190 may not cover the upper surfaces of the gate capping patterns 145.

The interlayer insulating film 190 may include at least one of silicon oxide, silicon nitride, silicon oxynitride, or a low-k dielectric material.

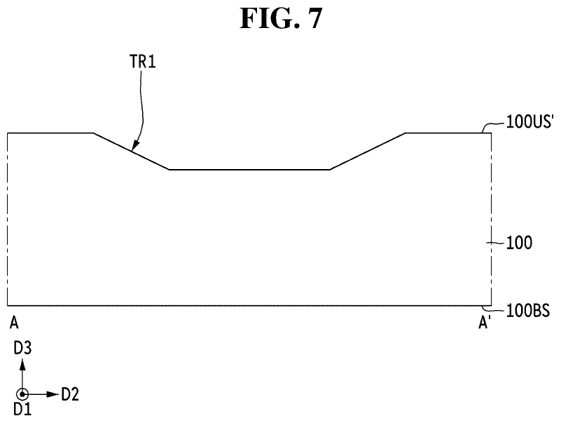

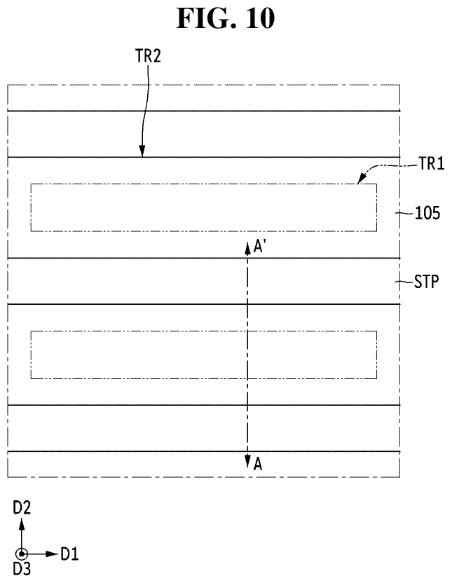

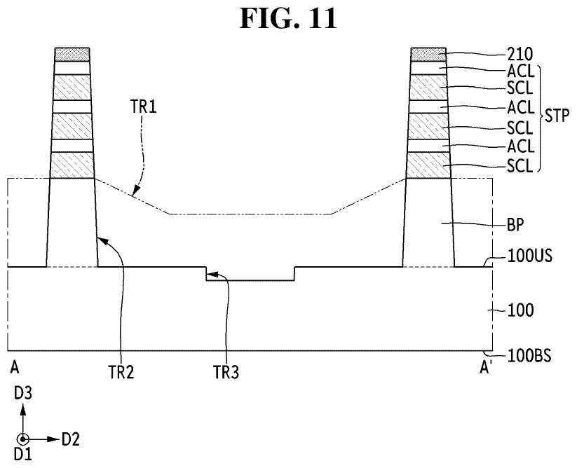

FIGS. 6 through 14 are diagrams for explaining a method for fabricating a semiconductor device according to some example embodiments. For reference, FIGS. 7 through 9 are cross-sectional views taken along line A-A′ of FIG. 6 according to some example embodiment, and FIGS. 11 through 14 are cross-sectional views taken along line A-A′ of FIG. 10, according to some example embodiments.

Referring to FIGS. 6 and 7, first trenches TR1 are formed in a substrate 100.

The substrate 100 may include an upper surface 100US′ and a lower surface 100BS that are opposite to each other in a third direction D3. The first trenches TR1 may be recessed toward the lower surface 100BS of the substrate 100. The first trenches TR1 may have a step difference from the upper surface 100US′ to the lower surface 100BS of the substrate 100. For example, the first trenches TR1 may extend in a first direction D1 and may be spaced apart from each other in a second direction D2. The sidewalls of the first trenches TR1 may have a sloped or vertical inclination.

Thereafter, well regions may be formed on the upper part of the substrate 100. A p-well region may be formed in the substrate 100 using a first photoresist pattern as an ion implantation mask that exposes the region where an n-type transistor is to be formed. After the first photoresist pattern is removed, an n-well region may be formed in the substrate 100 using a second photoresist pattern as an ion implantation mask that exposes the region where a p-type transistor is to be formed. The second photoresist pattern is then removed.

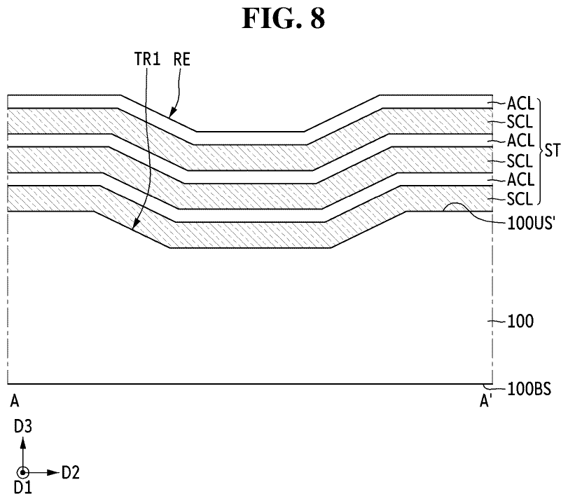

Referring to FIG. 8, a stacked structure ST is formed on the substrate 100.

The stacked structure ST may include sacrificial layers SCL and active layers ACL that are alternately stacked on the upper surface 100US′ of the substrate 100. The sacrificial layers SCL and the active layers ACL may be stacked in the third direction D3. The sacrificial layers SCL and the active layers ACL may each be formed on the substrate 100 by epitaxial growth. For example, the sacrificial layers SCL may include SiGe, and the active layers ACL may include Si.

The lowermost sacrificial layer SCL may extend along the profile of the substrate 100 and the first trenches TR1. The active layers ACL may extend along the profile of the respective underlying sacrificial layers SCL. The sacrificial layers SCL may extend along the profile of the respective overlying active layers ACL. Thus, the sacrificial layers SCL and the active layers ACL may have a curved surface or a step difference in the region overlapping with the first trenches TR1 in the third direction Z. In other words, the upper surface of the stacked structure ST may include recesses RE that overlap the first trenches TR1 and extend in the third direction D3. The recesses RE may be recessed toward the substrate 100. The sidewalls of the recesses RE may have, for example, a sloped inclination.

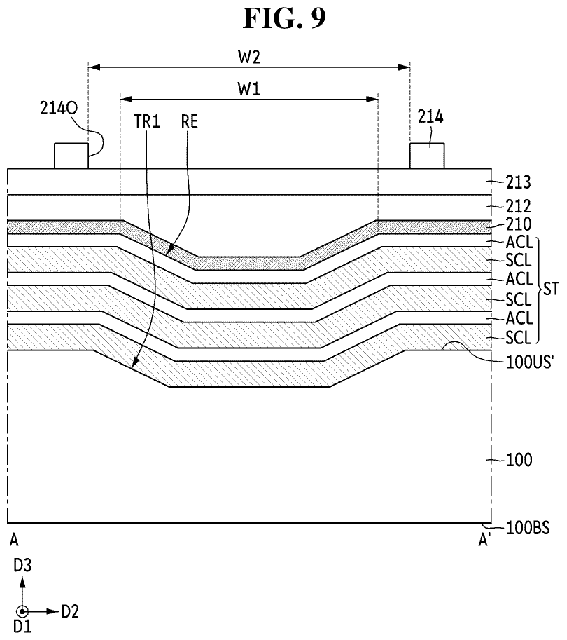

Referring to FIG. 9, a stopper film 210, a hard mask film 212, a photoresist film 213, and mask patterns 214 are sequentially formed on the stacked structure ST.

The stopper film 210 may be formed along the profile of the stacked structure ST. The stopper film 210 may include, for example, silicon nitride. In some example embodiments, silicon oxide may also be formed between the stopper film 210 and the stacked structure ST. The stopper film 210 and the silicon oxide may be formed through a deposition process, such as chemical vapor deposition (CVD), sputtering, atomic layer deposition (ALD), or physical vapor deposition (PVD).

The hard mask film 212 may be formed on the stopper film 210. The hard mask film 212 may include, for example, a spin-on hard mask (SOH) or silicon oxynitride. The hard mask film 212 may be a single-layer film or a multi-layer film.

The photoresist film 213 may be formed on the hard mask film 212.

The mask patterns 214 may be formed on the photoresist film 213. The mask patterns 214 may be for forming second trenches TR2, where an element isolation film 105 of FIG. 10 is to be formed. The mask patterns 214 may include openings 214O.

The mask patterns 214 may be aligned using the first trenches TR1. The alignment of the mask patterns 214 at target locations may be determined using the first trenches TR1. Because first photoresist patterns and second photoresist patterns used during the formation of the well regions are removed after the well regions are formed, the mask patterns 214 may be aligned with the well regions using the first trenches TR1.

In some example embodiments, the openings 214O may overlap at least parts of the first trenches TR1 in the third direction D3. The openings 214O may overlap the first trench TR1 in the third direction D3. On a plane including the first and second directions D1 and D2, the width of the openings 214O may be greater than or equal to the width of the first trenches TR1. The mask patterns 214 do not overlap the recesses RE in the third direction D3.

In some example embodiments, the openings 214O may overlap the recesses RE in the third direction D3. On a plane including the first and second directions D1 and D2, the width of the openings 214O may be greater than or equal to the width of the recesses RE. For example, in the second direction D2, a width W2 of the openings 214O may be greater than a width W1 of the recesses RE.

Referring to FIGS. 9 through 11, second trenches TR2 are formed by etching the stopper film 210, the stacked pattern STP, and the substrate 100 using the mask patterns 214.

By performing exposure and development processes on the photoresist film 213 using the mask patterns 214, photoresist patterns may be formed. The photoresist patterns may include openings corresponding to the openings 214O. The second trenches TR2 may be formed by etching the hard mask film 212, the stopper film 210, the stacked structure ST, and the substrate 100 using the photoresist patterns as an etch mask.

The second trenches TR2 may be formed deeper than the first trenches TR1. The first trenches TR1 may be removed as a result of the formation of the second trenches TR2. Accordingly, a substrate 100 having an upper surface 100US and a lower surface 100BS may be formed. The second trenches TR2 may define the upper surface 100US of the substrate 100. The upper surface 100US of the substrate 100 after the formation of the second trenches TR2 may be lower than the upper surface 100US′ of the substrate 100 before the formation of the second trenches TR2.

Lower patterns BP and stacked patterns STP may be defined by the second trenches TR2. That is, the lower patterns BP may be formed by patterning parts of the substrate 100, and the stacked patterns STP may be formed by patterning the stacked structure ST. The stacked patterns STP may include the patterned channel layers ACL and the patterned sacrificial layers SCL. The lower patterns BP may protrude from the upper surface 100US of the substrate 100. The stacked patterns STP may be formed on the lower patterns BP.

The recesses RE are removed as a result of the formation of the second trenches TR2. The stopper film 210 is removed from within the recesses RE by the formation of the second trenches TR2. The stopper film 210 may remain only on the stacked patterns STP.

In some example embodiments, during the formation of the second trenches TR2, third trenches TR3 may also be formed in the substrate 100. The third trenches TR3 may result from the recesses RE and/or the first trenches TR1. The third trenches TR3 may be recessed toward the lower surface 100BS of the substrate 100. The third trenches TR3 may have a step difference from the upper surface 100US of the substrate 100 toward the lower surface 100BS of the substrate 100. In other words, the bottom surfaces of the second trenches TR2 may have a step difference.

In some example embodiments, contrary to what is illustrated, the third trenches TR3 may not be formed in the substrate 100 during the formation of the second trenches TR2, depending on the conditions of the process of forming the second trenches TR2 (e.g., the width and depth of the second trenches TR2). In this case, a semiconductor device including only the second trenches TR2, as illustrated in FIGS. 2 and 3, may be formed. That is, the bottom surfaces of the second trenches TR2 may not include a step difference.

Thereafter, the mask patterns 214, the photoresist patterns, and the hard mask film 212 are removed.

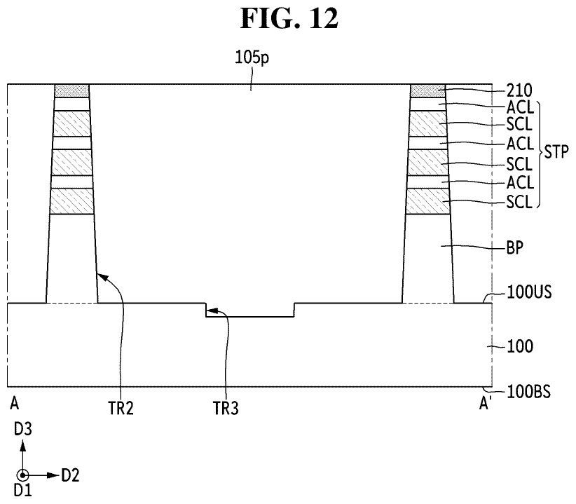

Referring to FIG. 12, a preliminary element isolation film 105p is formed.

The preliminary element isolation film 105p may be formed to cover the substrate 100, the lower patterns BP, the stacked patterns STP, and the stopper film 210. A planarization process may be performed on the preliminary element isolation film 105p. The planarization process may include a chemical mechanical polishing (CMP) process. The stopper film 210 may function as a polish stopper film during the planarization process. The preliminary element isolation film 105p may be polished until the upper surface of the stopper film 210 is exposed. Thus, a preliminary element isolation film 105p filling the second trenches TR2 and the third trenches TR3 may be formed.

The preliminary element isolation film 105p may include, for example, an oxide film, a nitride film, an oxynitride film, or a combination thereof. The preliminary element isolation film 105p may be a single-layer film or a multi-layer film.

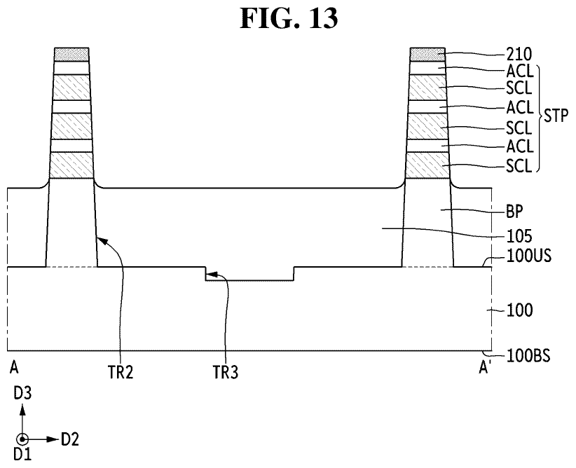

Referring to FIG. 13, an element isolation film 105 is formed by removing part of the preliminary element isolation film 105p. The element isolation film 105 may be formed on the substrate 100. The element isolation film 105 may fill the second trenches TR2 and the third trenches TR3. The stacked patterns STP may protrude above the element isolation film 105.

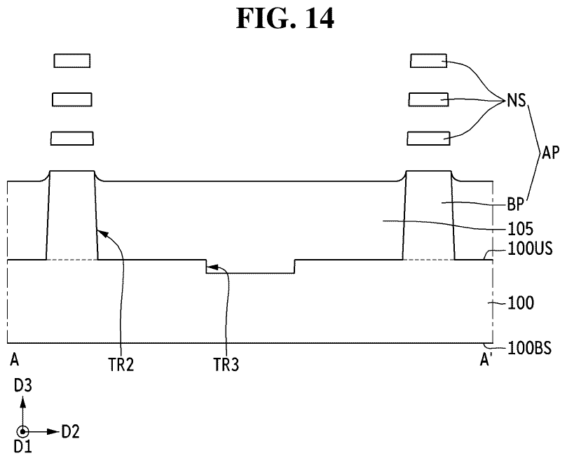

Referring to FIGS. 13 and 14, the stopper film 210 may be removed. The stopper film 210 may be removed through, for example, a stripping process.

Thereafter, the sacrificial layers SCL of the stacked patterns STP are removed, forming sheet patterns NS on each of the lower patterns BP. The sheet patterns NS may be formed on the lower patterns BP to be spaced apart from the lower patterns BP in the third direction D3. The channel layers ACL of the stacked patterns STP may become the sheet patterns NS. Thus, active patterns AP including the lower patterns BP and the sheet patterns NS may be formed.

Thereafter, referring to FIG. 2, a gate insulating film 130 and gate electrodes 120 may be formed on the element isolation film 105 and the active patterns AP.

When the element isolation film 105 is formed on parts of the stopper film 210 that correspond to openings 214O using the mask patterns 214, an element isolation film 105 that fills the recesses RE may be formed on the stopper film 210 extending along the recesses RE. In this case the stopper film 210 may may remain below the element isolation film 105, instead of being removed, or the removal of the stopper film 210 may cause the element isolation film 105 to be lifted. In other words, the presence of the stopper film 210 within the recesses RE may cause defects in the semiconductor device.

However, in the method for fabricating a semiconductor device according to some example embodiments, because the stopper film 210 is removed from within the recesses RE during the formation of the second trenches TR2, the element isolation film 105 is formed in the second trenches TR2 without the stopper film 210. Therefore, the issues of the stopper film 210 remaining below the element isolation film 105 and the element isolation film 105 being lifted due to the removal of the stopper film 210 can be reduced or prevented, resulting in a semiconductor device with improved reliability.

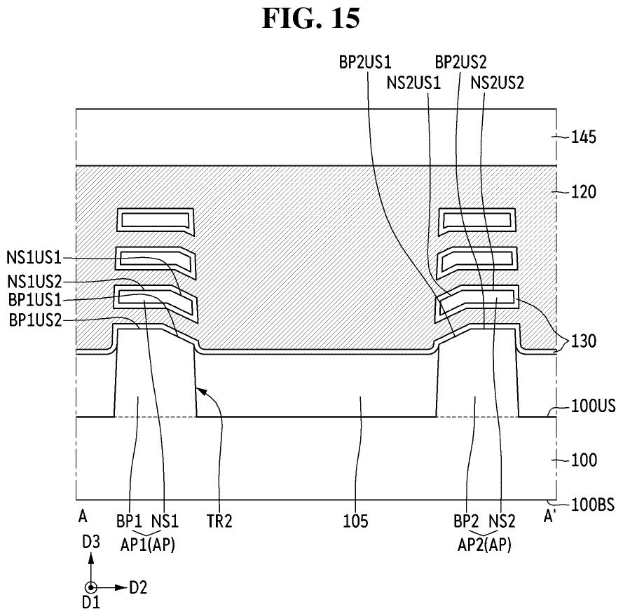

FIG. 15 is a diagram for explaining a semiconductor device according to some example embodiments. For reference, FIG. 15 is a cross-sectional view taken along line A-A′ of FIG. 1, according to some example embodiments. For convenience, overlapping content with FIGS. 1 through 14 will be briefly described, with a focus on the differences.

Referring to FIG. 15, in the semiconductor device according to some example embodiments, at least parts of the upper surface of first and second lower patterns BP1 and BP2 may be inclined relative to an upper surface 100US of a substrate 100.

For example, active patterns AP may include a first active pattern AP1 and a second active pattern AP2 that are adjacent to each other. The first active pattern AP1 may include the first lower pattern BP1 that protrudes from the upper surface 100US of the substrate 100, and a plurality of first sheet patterns NS1 that are spaced apart from each other in a third direction D3 on the first lower pattern BP1. The second active pattern AP2 may include the second lower pattern BP2 that protrudes from the upper surface 100US of the substrate 100, and a plurality of second sheet patterns NS2 that are spaced apart from each other in the third direction D3 on the second lower pattern BP2.

The upper surface of the first lower pattern BP1 may include a first portion BP1US1 and a second portion BP1US2. The first portion BP1US1 may be inclined relative to the upper surface 100US of the substrate 100. The second portion BP1US2 may be flat. The first portion BP1US1 may have a negative inclination. The upper surface of the second lower pattern BP2 may include a first portion BP2US1 and a second portion BP2US2. The first portion BP2US1 may be inclined relative to the upper surface 100US of the substrate 100. The second portion BP2US2 may be flat. The first portion BP2US1 may have a positive inclination. The positive and negative inclinations are defined relative to the third direction D3. The first portion BP1US1 of the first lower pattern BP1 and the first portion BP2US1 of the second lower pattern BP2 may be adjacent to an element isolation film 105 between the first and second lower patterns BP1 and BP2.

In some example embodiments, at least part of the upper surface of at least one of the sheet patterns (NS1 and NS2) may be inclined relative to the upper surface 100US of the substrate 100.

For example, the upper surface of a lowermost first sheet pattern NS1 may include a first portion NS1US1 and a second portion NS1US2. The first portion NS1US1 may be inclined relative to the upper surface 100US of the substrate 100. The second portion NS1US2 may be flat. The first portion NS1US1 may have a negative inclination. The upper surface of a lowermost second sheet pattern NS2 may include a first portion NS2US1 and a second portion NS2US2. The first portion NS2US1 may be inclined relative to the upper surface of the substrate 100. The second portion NS2US2 may be flat. The first portion NS2US1 may have a positive inclination.

At least part of the lower surface of at least one of the sheet patterns (NS1 and NS2) may also be inclined relative to the upper surface 100US of the substrate 100. For example, the lower surface of the lowermost first sheet pattern NS1 may include a first portion with a negative inclination and a second portion that is flat. The lower surface of the lowermost second sheet pattern NS2 may include a first portion with a positive inclination and a second portion that is flat. In other words, at least one of the sheet patterns (NS1 and NS2) may include a portion that extends parallel to the upper surface 100US of the substrate 100 (e.g., in a second direction D2) and a portion that extends in a diagonal direction. For example, the lowermost first sheet pattern NS1 may include a portion that extends in the second direction D2 and a portion that extends in a direction between the opposite direction of the second direction D2 and the third direction D3. The lowermost second sheet pattern NS2 may include a portion that extends in the second direction D2 and a portion that extends in a direction between the second and third directions D2 and D3.

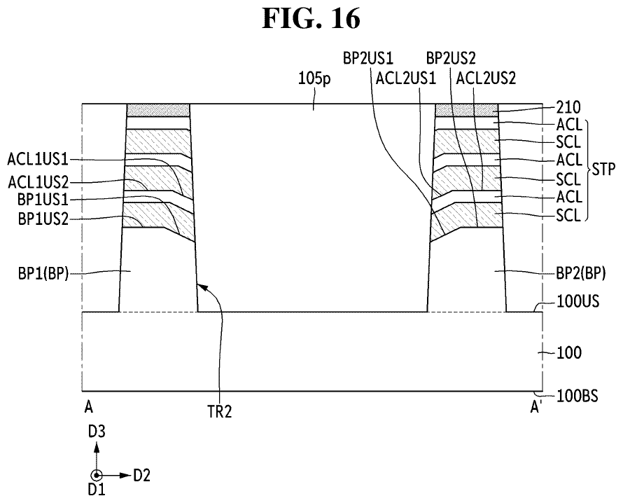

FIG. 16 is a diagram for explaining a method for fabricating a semiconductor device according to some example embodiments. For reference, FIG. 16 illustrates steps following those in FIG. 9. For convenience, overlapping content with FIGS. 1 through 15 will be briefly described, with a focus on the differences.

Referring to FIGS. 9 and 16, in some example embodiments, the shape of lower patterns BP and active layers ACL may vary depending on the position and size of openings 214O of mask patterns 214.

For example, the openings 214O may overlap recesses RE and with portions of first trenches TR1. Thus, at least parts of the upper surfaces of the lower patterns BP may be inclined relative to an upper surface 100US of a substrate 100. At least parts of the upper surfaces of the active layers ACL and at least parts of the upper surfaces of sacrificial layers SCL may also be inclined relative to the upper surface 100US of the substrate 100.

The lower patterns BP may include a first lower pattern BP1 and a second lower pattern BP2 that are adjacent to each other. The upper surface of the first lower pattern BP1 may include a first portion BP1US1 that is inclined relative to the upper surface 100US of the substrate 100 and a second portion BP1US2 that is flat. The upper surfaces of the active layers ACL on the first lower pattern BP1 may each include a first portion ACL1US1 that is inclined relative to the upper surface 100US of the substrate 100 and a second portion ACL1US2 that is flat. The first portion ACL1US1 may have a negative inclination. The upper surface of the second lower pattern BP2 may include a first portion BP2US1 that is inclined relative to the upper surface 100US of the substrate 100 and a second portion BP2US2 that is flat. The upper surfaces of the active layers ACL on the second lower pattern BP2 may each include a first portion ACL2US1 that is inclined relative to the upper surface 100US of the substrate 100 and a second portion ACL2US2 that is flat. The first portion ACL2US1 may have a positive inclination. At least part of the lower surface of at least one of a plurality of active patterns AP may also be inclined relative to the upper surface 100US of the substrate 100.

Thereafter, the semiconductor device of FIG. 16 may be obtained by performing the method described above with reference to FIGS. 10 through 14.

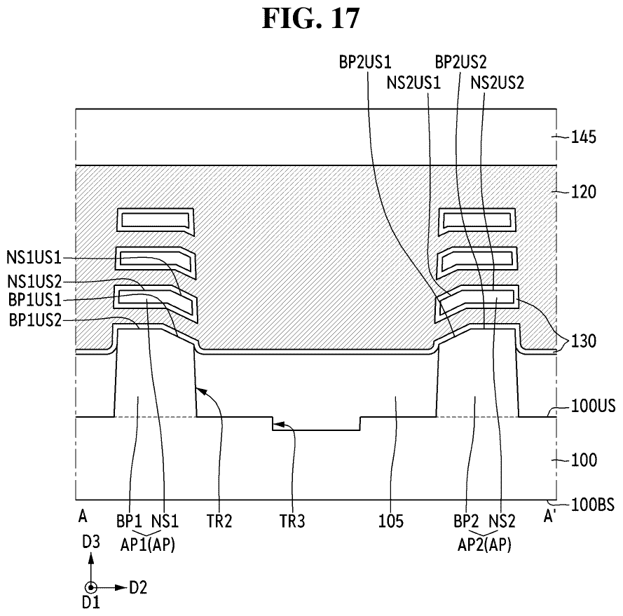

FIG. 17 is a diagram for explaining a semiconductor device according to some example embodiments. For reference, FIG. 17 is an exemplary cross-sectional view taken along line A-A′ of FIG. 1. For convenience, overlapping content with FIG. 15 will be briefly described, with a focus on the differences.

Referring to FIG. 17, in the semiconductor device according to some example embodiments, a substrate 100 between adjacent active patterns AP may include a third trench TR3. The substrate 100 between a first lower pattern BP1 and a second lower pattern BP2 may include the third trench TR3.

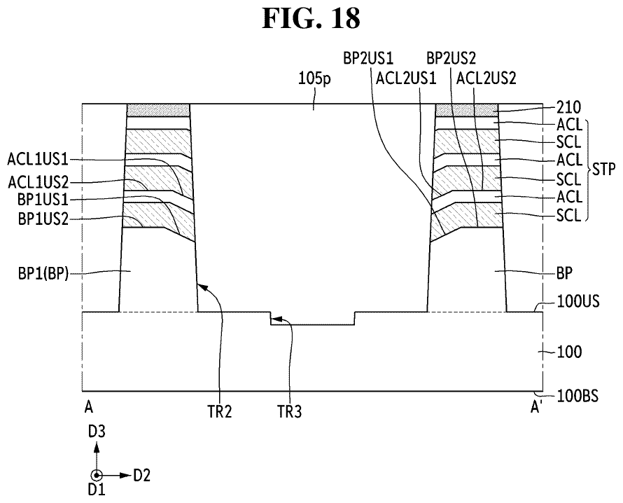

FIG. 18 is a diagram for explaining a method for fabricating a semiconductor device according to some example embodiments. For reference, FIG. 18 illustrates steps following those in FIG. 9. For convenience, overlapping content with FIGS. 1 through 17 will be briefly described, with a focus on the differences.

Referring to FIGS. 9 and 18, in some example embodiments, during the formation of a second trench TR2, a third trench TR3 may also be formed in a substrate 100. The third trench TR3 may result from a recess RE and/or a first trench TR1.

Thereafter, the semiconductor device shown in FIG. 18 may be obtained by performing the method described above with reference to FIGS. 10 through 14.

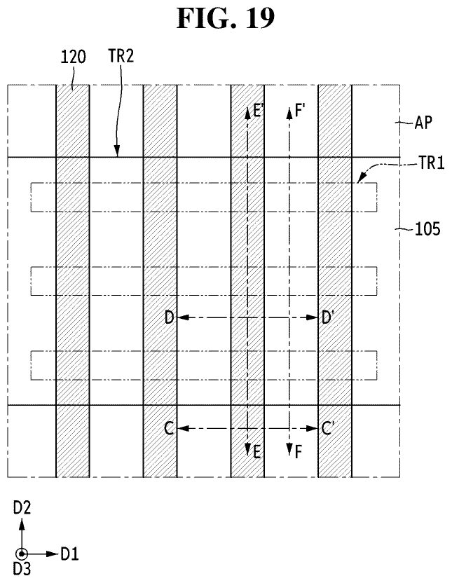

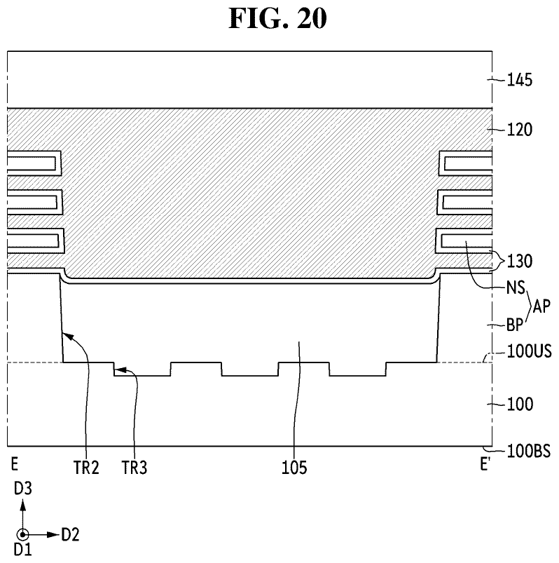

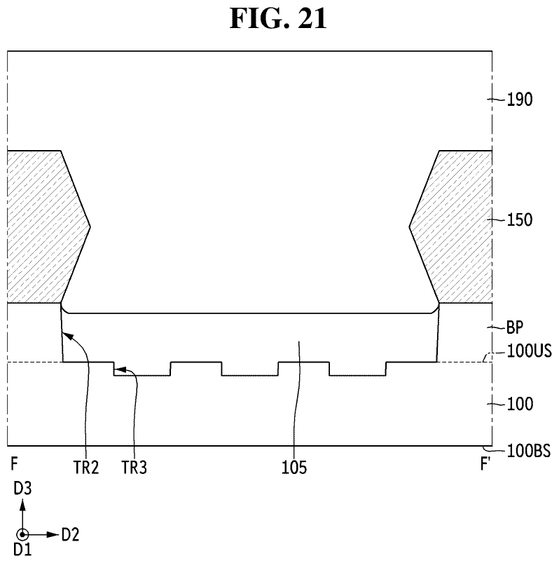

FIGS. 19 through 21 are diagrams for explaining a semiconductor device according to some example embodiments. For reference, FIG. 20 is a cross-sectional view taken along line E-E′ of FIG. 19, and FIG. 21 is a cross-sectional view taken along line F-F′ of FIG. 19. FIGS. 4 and 5 are cross-sectional views taken along lines C-C′ and D-D′ of FIG. 19, respectively. For convenience, overlapping content with FIGS. 1 through 14 will be briefly described, with a focus on the differences.

Referring to FIGS. 19 through 21, in some example embodiments, there may be multiple third trenches TR3. A substrate 100 between adjacent active patterns AP may include the multiple third trenches TR3. The multiple third trenches TR3 may be formed in a single second trench TR2. For example, the multiple third trenches TR3 may be spaced apart from each other in a second direction D2. The multiple third trenches TR3 may result from, for example, a first trench TR1. The multiple third trenches TR3 may be formed at a position corresponding to the first trench TR1.

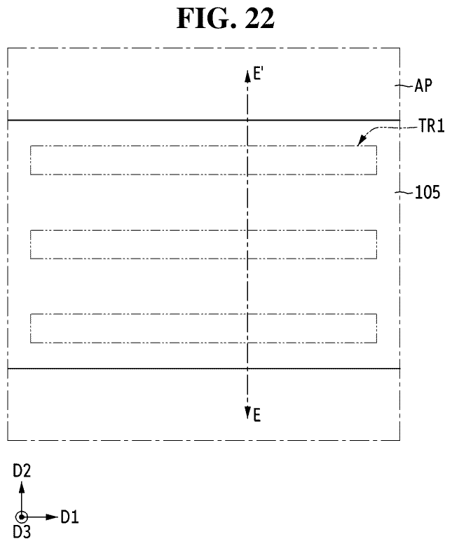

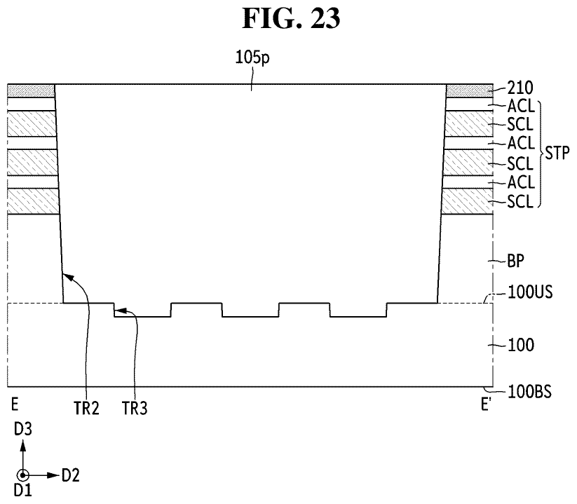

The single second trench TR2 may be formed to be aligned with multiple first trenches TR1. The single second trench TR2 may be formed in a region overlapping with the multiple first trenches TR1 in a third direction D3. The multiple first trenches TR1 may be removed during the formation of the single second trench TR2. The multiple first trenches TR1 will hereinafter be explained in detail with reference to FIGS. 22 and 23.

FIGS. 22 and 23 are diagrams for explaining a method for fabricating a semiconductor device according to some example embodiments. For reference, FIG. 23 is a cross-sectional view taken along line E-E′ of FIG. 22, and FIGS. 22 and 23 illustrate steps following those in FIG. 9. For convenience, overlapping content with FIGS. 1 through 21 will be briefly described, with a focus on the differences.

Referring to FIGS. 9, 21, and 22, in some example embodiments, the width of a second trench TR2 may vary depending on the size of an opening 214O of a mask pattern 214.

For example, the opening 214O may overlap multiple first trenches TR1. Thus, multiple third trenches TR3 may be formed in the second trench TR2. The multiple third trenches TR3 may result from the multiple first trenches TR1.

Thereafter, the semiconductor device of FIG. 20 may be obtained by performing the method described above with reference to FIGS. 10 through 14.

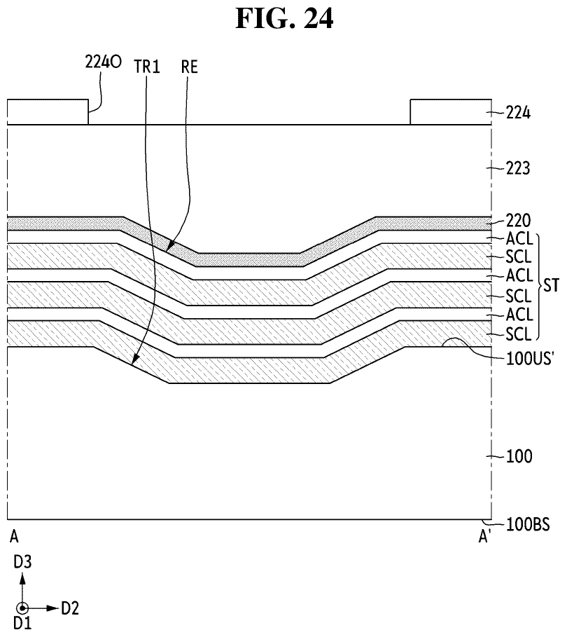

FIGS. 24 through 26 are diagrams for explaining a method for fabricating a semiconductor device according to some example embodiments. For reference, FIG. 24 illustrates steps following those in FIG. 8. For convenience, overlapping content with FIGS. 1 through 15 will be briefly described, with a focus on the differences.

Referring to FIG. 24, a stopper film 220, a photoresist film 223, and a mask pattern 224 are sequentially formed on a stacked structure ST.

The stopper film 220 may be formed along the profile of the stacked structure ST. The stopper film 220 may include, for example, silicon nitride. In some example embodiments, silicon oxide may also be formed between the stopper film 220 and the stacked structure ST. The stopper film 220 and the silicon oxide may be formed through a deposition process, such as CVD, sputtering, ALD, or PVD.

The photoresist film 223 may be formed on the stopper film 220.

The mask pattern 224 may be formed on the photoresist film 223. The mask pattern 224 may be for removing the stopper film 220 from within a recess RE. The mask pattern 224 may include an opening 2240. The opening 2240 may overlap the recess RE in a third direction D3. The width of the opening 2240 may be greater than or equal to the width of the recess RE. The mask pattern 224 does not overlap the recess RE in the third direction D3.

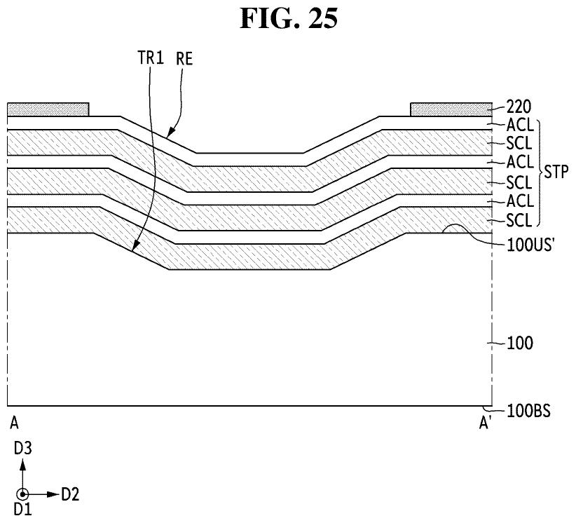

Referring to FIGS. 24 and 25, by performing exposure and development processes on the photoresist film 223 using the mask pattern 224, a photoresist pattern may be formed. The photoresist pattern may include an opening corresponding to the openings 2240. The stopper film 220 may be etched using the photoresist pattern as an etch mask to expose the recess RE of the stacked pattern STP. That is, the stopper film 220 within the recess RE may be removed. Depending on the size of the opening 2240, part of the stopper film 220 on the flat upper surface of the stacked pattern STP connected to the recess RE may also be removed.

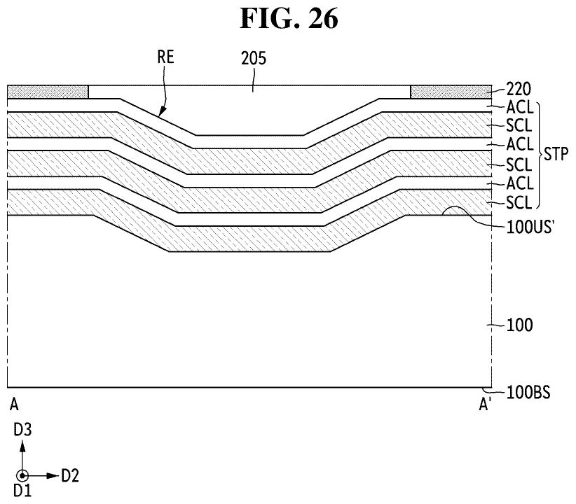

Referring to FIG. 26, a sub-element isolation film 205 may be formed on part of the stacked pattern STP exposed by the stopper film 220. The sub-element isolation film 205 may fill the recess RE. The sub-element isolation film 205 may include, for example, an oxide film, a nitride film, an oxynitride film, or a combination thereof. An element isolation film 105 may be a single-layer film or a multi-layer film.

That is, an additional process for removing the stopper film 220 from within the recess RE may be added. Thereafter, a second trench TR2 and the element isolation film 105 may be formed using a mask pattern for forming a second trench TR2 where the element isolation film 105 is formed. Because the stopper film 220 has been removed from within the recess RE, the element isolation film 105 may be formed at various locations according to the design, and defects in the semiconductor device caused by the removal of the stopper film 220 can be reduced or prevented.

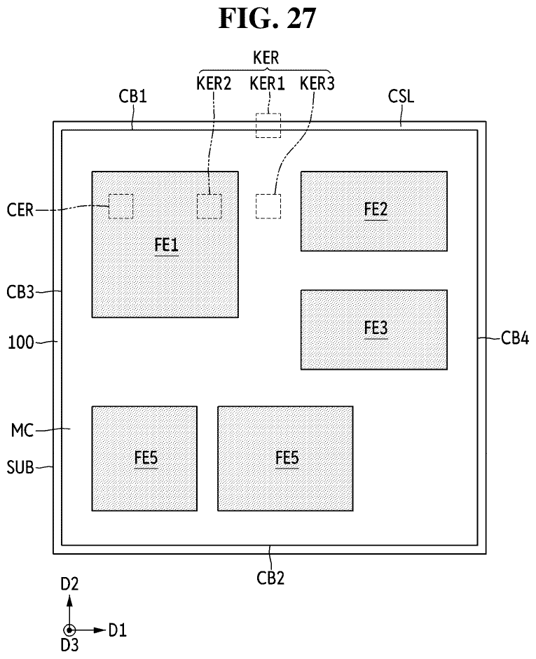

FIG. 27 is a diagram for explaining a semiconductor device according to some example embodiments. For convenience, overlapping content with FIGS. 1 through 26 will be briefly described, with a focus on the differences.

Referring to FIG. 27, the semiconductor device according to some example embodiments may include a main chip MC and a diced scribe lane CSL surrounding the main chip MC. The main chip MC may include first through fifth functional elements FE1 through FE5 on a substrate 100. The substrate 100 may be a diced semiconductor wafer. The substrate 100 may support the first through fifth functional elements FE1 through FE5.

The main chip MC may include first through fourth boundaries CB1 through CB4. The first through fourth boundaries CB1 through CB4 may be defined between the diced scribe lane CSL and the main chip MC. The diced scribe lane CSL may surround the first through fourth boundaries CB1 through CB4 of the main chip MC. In one example embodiment, the diced scribe lane CSL may include a first key region KER1 adjacent to the first boundary CB1 of the main chip MC. In other words, the first key region KER1 may remain on the diced scribe lane CSL even after the dicing of the substrate 100.

The first through fifth functional elements FE1 through FE5 may be functional blocks that form an integrated circuit (IC). Each of the first through fifth functional elements FE1 through FE5 may include any one of a memory block, an analog logic block, an input/output (I/O) logic block, a central processing unit (CPU) block, or a radio frequency (RF) block.

For example, the first functional element FE1 may include a logic cell region CER and a second key region KER2. In other words, a key region KER may be provided not only in the diced scribe lane CSL but also within functional blocks. A third key region KER3 may be provided in the area between the first and second functional elements FE1 and FE2.

In some example embodiments, the key region KER may include the first, second, and third key regions KER1, KER2, and KER3, which are positioned at different locations on the semiconductor device. At least one of the first, second, or third key regions KER1, KER2, or KER3 may be omitted. The key region KER may include a pattern that comprises an overlay key, an alignment key, or a combination thereof.

For example, the semiconductor devices described above with reference to FIGS. 1 through 26 may be disposed in the cell region CER. During the fabrication of the semiconductor devices, the first trenches TR1 may be formed in the cell region CER. The second trenches TR2 alone, or both the second trenches TR2 and the third trenches TR3, may be formed in the cell region CER.

In another example, the semiconductor devices described above with reference to FIGS. 1 through 26 may be disposed in the key region KER. During the fabrication of the semiconductor devices, the first trenches TR1 may be formed in the key region KER. The second and third trenches TR2 and TR3 may be formed in the key region KER. In this case, the active patterns AP in FIGS. 1 through 26 may be dummy active patterns, and the gate electrodes 120 may be dummy gate electrodes. The dummy gate electrodes are not connected to gate contacts. In some example embodiments, contrary to what is illustrated, the gate structures GS may be omitted.

In yet another example, the semiconductor devices described above with reference to FIGS. 1 through 26 may be disposed in both the cell region CER and the key region KER. During the fabrication of the semiconductor devices, the first trenches TR1 may be formed in both the cell region CER and the key region KER. The second trenches TR2 alone, or both the second trenches TR2 and the third trenches TR3, may be formed in both the cell region CER and the key region KER.

In still another example, the semiconductor devices described with reference to FIGS. 1 through 26 may be disposed in the key region KER and not in the cell region CER. In this case, the semiconductor device of FIGS. 1 through 5 excluding the third trenches TR3 may be disposed in the cell region CER. Because no first trenches TR1 are formed in the cell region CER, the third trenches TR3 may not be formed. That is, as illustrated in FIG. 15, the bottom surfaces of the second trenches TR2 may not have a step difference. For example, when the semiconductor device of FIG. 15 is disposed in the key region KER, at least parts of the upper surfaces of the lower patterns BP in the key region KER may be inclined relative to the upper surface 100US of the substrate 100, as illustrated in FIG. 15, whereas the upper surfaces of the lower patterns BP in the cell region CER may be flat, as illustrated in FIG. 2.

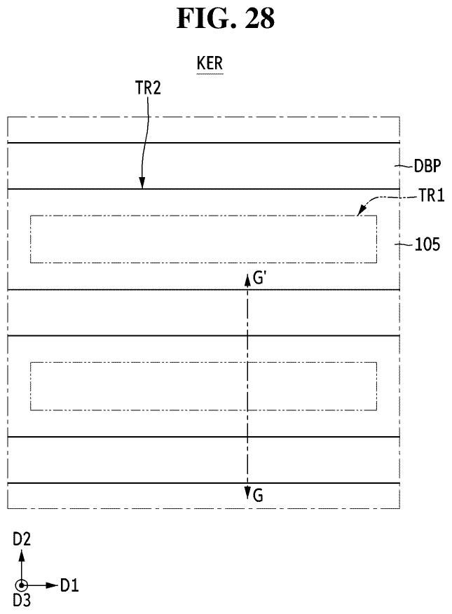

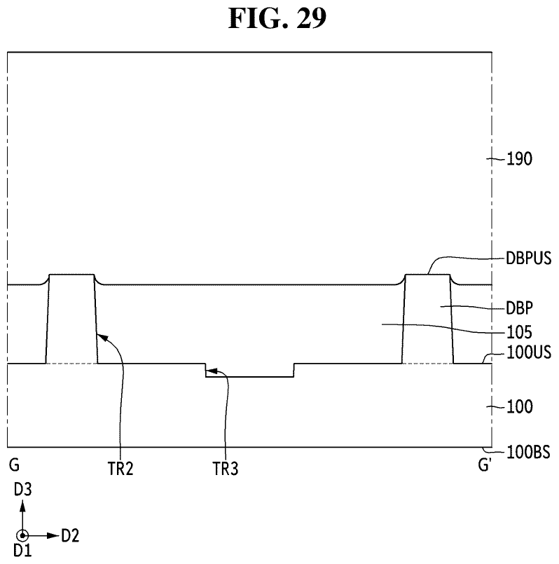

FIG. 28 is a layout view for explaining the key region of FIG. 27. FIGS. 29 through 31 are cross-sectional views taken along line G-G′ of FIG. 28. For convenience, overlapping content with FIGS. 1 through 26 will be briefly described, with a focus on the differences.

Referring to FIGS. 28 through 31, in some example embodiments, dummy lower patterns DBP may protrude from a substrate 100. The dummy lower patterns DBP may protrude from an upper surface 100US of the substrate 100. The dummy lower patterns DBP may extend longitudinally in a first direction D1. The dummy lower patterns DBP may be defined by second trenches TR2. No dummy sheet patterns may be formed on the dummy lower patterns DBP. The dummy lower patterns DBP may include the same material as lower patterns BP. An element isolation film 105 may surround at least parts of the dummy lower patterns DBP. The element isolation film 105 is not disposed on the upper surfaces of the dummy lower patterns DBP.

First trenches TR1 may be formed in a key region KER. The second trenches TR2 may be formed to be aligned with the first trenches TR1. The second trenches TR2 may be formed in regions overlapping the first trenches TR1 in a third direction D3. The first trenches TR1 may be removed during the formation of the second trenches TR2.

An interlayer insulating film 190 may cover the key region KER. The interlayer insulating film 190 may cover the element isolation film 105 and the dummy lower patterns DBP.

In some example embodiments, no dummy gate electrodes may be disposed in the key region KER. In some example embodiments, contrary to what is illustrated, dummy gate electrodes may be disposed on the key region KER.

Referring to FIG. 29, in some example embodiments, upper surfaces DBPUS of the dummy lower patterns DBP may be flat.

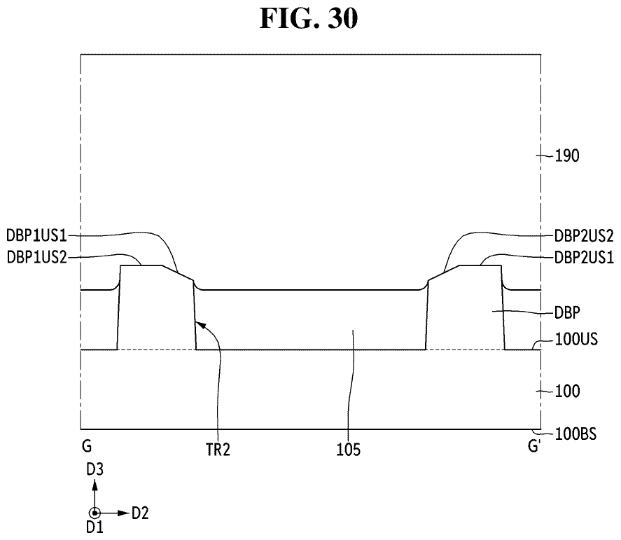

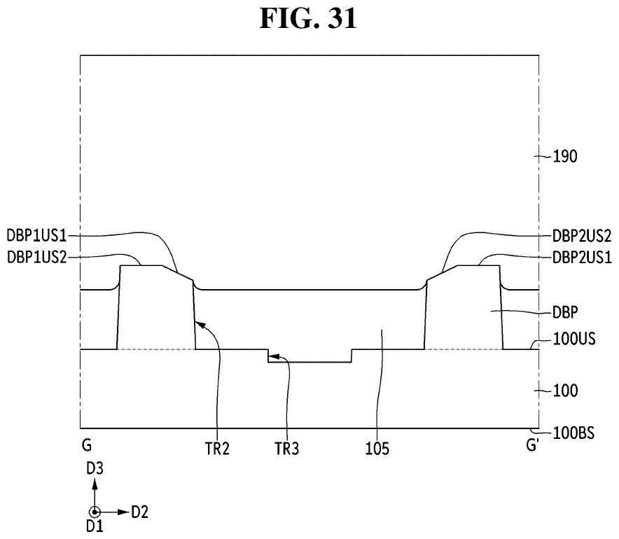

Referring to FIGS. 30 and 31, in some example embodiments, at least parts of the upper surfaces DBPUS of the dummy lower patterns DBP may be inclined relative to the upper surface 100US of the substrate 100.

For example, the upper surface DBPUS of the dummy lower pattern DBP on one side of the element isolation film 105 may include a first portion DBP1US1 and a second portion DBP1US2. The first portion DBP1US1 may be inclined relative to the upper surface 100US of the substrate 100. The second portion DBP1US2 may be flat. The first portion DBP1US1 may have a negative inclination. The upper surface DBPUS of the dummy lower pattern DBP on the other side of the element isolation film 105 may include a first portion DBP2US1 and a second portion DBP2US2. The first portion DBP2US1 may be inclined relative to the upper surface 100US of the substrate 100. The second portion DBP2US2 may be flat. The first portion DBP2US1 may have a positive inclination.

Referring to FIG. 30, in some example embodiments, the bottom surfaces of the second trenches TR2 may not have a step difference.

Referring to FIGS. 29 and 31, in some example embodiments, the substrate 100 between adjacent dummy lower patterns DBP may include the third trenches TR3. The third trenches TR3 may result from the first trenches TR1.

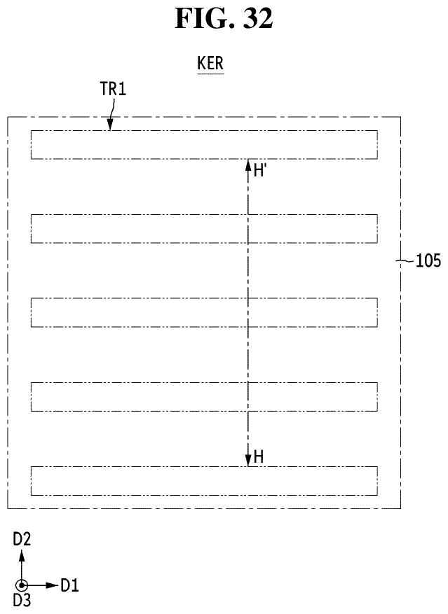

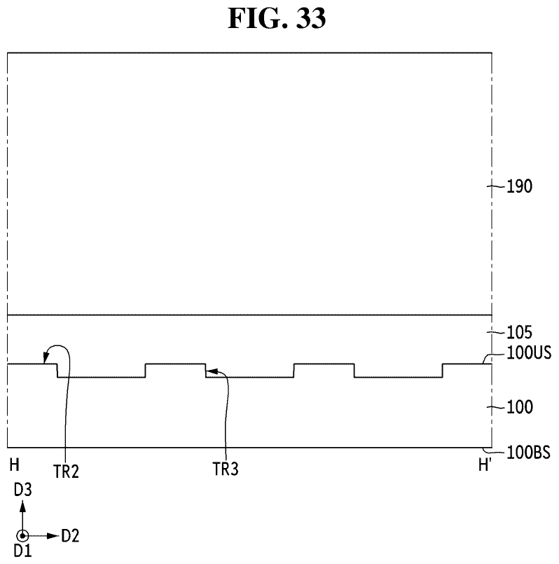

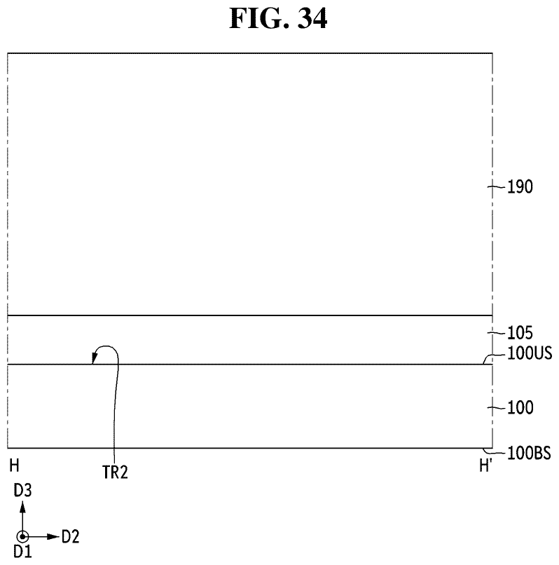

FIG. 32 is a layout view for explaining the key region of FIG. 27. FIGS. 33 and 34 are cross-sectional views taken along line H-H′ of FIG. 32. For convenience, overlapping content with FIGS. 1 through 31 will be briefly described, with a focus on the differences. For convenience, the second trenches TR2 and third trenches TR3 are omitted in FIG. 32.

Referring to FIGS. 32 through 34, in some example embodiments, a single second trench TR2 may be formed to be aligned with multiple first trenches TR1. The second trench TR2 may be formed in a region overlapping with the first trenches TR1 in the third direction D3. The first trenches TR1 may be removed during the formation of the second trench TR2.

Referring to FIG. 33, multiple third trenches TR3 may be formed in the second trench TR2. The third trenches TR3 may result from the respective multiple first trenches TR1.

Referring to FIG. 34, the bottom surface of the second trench TR2 may not have a step difference. Depending on the conditions for forming the second trench TR2 (e.g., the width and depth of the second trench TR2), the third trenches TR3 may not be formed in the substrate 100 during the formation of the second trench TR2.

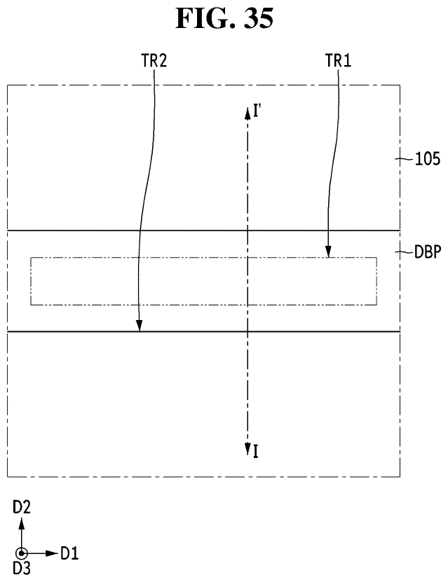

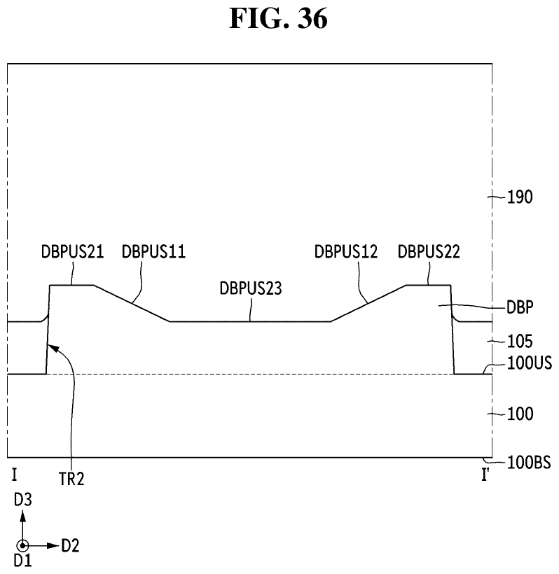

FIG. 35 is a layout view for explaining the key region of FIG. 27. FIG. 36 is a cross-sectional view taken along line I-I′ of FIG. 35. For convenience, overlapping content with FIGS. 1 through 31 will be briefly described, with a focus on the differences.

Referring to FIGS. 35 and 36, in some example embodiments, the upper surfaces of dummy lower patterns DBP may include first portions DBPUS11 and DBPUS12, which are inclined relative to the upper surface 100US of the substrate 100, and second portions DBPUS21, DBPUS22, and DBPUS23, which are flat. The first portion DBPUS11 may have a negative inclination, and the first portion DBPUS12 may have a positive inclination. The second portion DBPUS21, the first portion DBPUS11, the second portion DBPUS23, the first portion DBPUS12, and the second portion DBPUS22 may be sequentially connected. In other words, the upper surfaces of the dummy lower patterns DBP may include a recess.

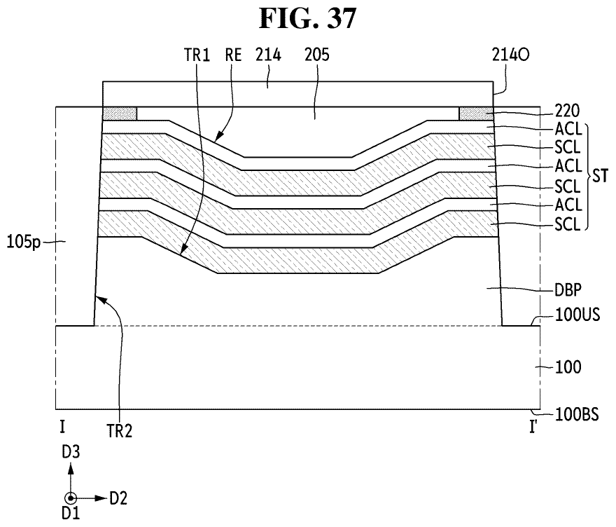

FIG. 37 is a diagram for explaining a method for fabricating a semiconductor device according to some example embodiments. For reference, FIG. 37 illustrates steps following those illustrated in FIG. 26. For convenience, overlapping content with FIGS. 1 through 36 will be briefly described, with a focus on the differences.

A dummy lower pattern DBP of FIG. 37 may be formed in the same manner as its counterpart of FIG. 26. The dummy lower pattern DBP of FIG. 37 may correspond to its counterpart of FIG. 26.

Referring to FIGS. 26 and 37, a mask pattern 214 may be formed on a stopper film 220 and a sub-element isolation film 205. The mask pattern 214 may be formed in a region overlapping with a first trench TR1 and the recesses RE. An opening 214O may expose the stopper film 220 in a region that does not overlap the first trench TR1 and the recess RE. A second trench TR2 may be formed by etching the stopper film 220, a stacked pattern STP, and a substrate 100 using the mask pattern 214. A preliminary element isolation film 105p filling the second trench TR2 may be formed.

Referring to FIGS. 36 and 37, the stacked pattern STP may be removed, and the preliminary element isolation film 105p may be patterned to form an element isolation film 105. Thus, the dummy lower pattern DBP of FIG. 36 may be formed.

While some example embodiments of the present disclosure have been described above with reference to the accompanying drawings, the inventive concepts are not limited to the above example embodiments and may be embodied in various other forms. It will be understood by those skilled in the art that other specific forms can be implemented without changing the technical spirit or essential characteristics of the inventive concepts. Therefore, the above-described example embodiments should be understood as being examples in all aspects and not limiting.

What is claimed is:

1. A semiconductor device comprising:
a substrate;
a first lower pattern on the substrate; and
an element isolation film on the substrate and surrounding at least parts of sidewalls of the first lower pattern,
wherein at least part of an upper surface of the first lower pattern is inclined relative to an upper surface of the substrate.

2. The semiconductor device of claim 1, further comprising:
a plurality of first sheet patterns stacked on the first lower pattern,
wherein at least part of an upper surface of at least one of the plurality of first sheet patterns is inclined relative to the upper surface of the substrate.

3. The semiconductor device of claim 2, wherein the upper surface of the at least one of the plurality of first sheet patterns includes a first portion that is inclined relative to the upper surface of the substrate and a second portion that is flat.

4. The semiconductor device of claim 2, further comprising:
a gate electrode surrounding the plurality of first sheet patterns on the first lower pattern.

5. The semiconductor device of claim 1, further comprising:
a second lower pattern on the substrate and spaced apart from the first lower pattern,
wherein relative to a vertical direction,
the at least part of the upper surface of the first lower pattern has a positive inclination, and
at least part of an upper surface of the second lower pattern has a negative inclination.

6. The semiconductor device of claim 1, wherein
the substrate includes a trench,
the trench does not overlap the first lower pattern in a direction perpendicular to the upper surface of the substrate, and
the element isolation film fills the trench.

7. The semiconductor device of claim 1, wherein
the substrate includes a plurality of trenches,
the plurality of trenches do not overlap the first lower pattern in a direction perpendicular to the upper surface of the substrate, and
the element isolation film fills the plurality of trenches.

8. The semiconductor device of claim 1, further comprising:
a second lower pattern on the substrate,
wherein
the element isolation film surrounds at least parts of sidewalls of the second lower pattern,
the substrate includes a key region and a logic cell region,
the first lower pattern is in the key region, and
the second lower pattern is in the logic cell region.

9. The semiconductor device of claim 8, wherein the upper surface of the second lower pattern includes a flat portion.

10. The semiconductor device of claim 8, wherein
the upper surface of the second lower pattern includes a first portion with a positive inclination, a second portion with a negative inclination, and a third portion that is flat.

11. A semiconductor device comprising:
a substrate including a logic cell region and a key region;
a first lower pattern on the substrate;
a second lower pattern on the substrate;
a trench in the substrate between the first and second lower patterns; and
an element isolation film filling the trench and surrounding at least parts of sidewalls of the first and second lower patterns,
wherein the first and second lower patterns are in the key region or in a region including a transistor of a first conductivity type and within the logic cell region.

12. The semiconductor device of claim 11, wherein the trench includes a plurality of trenches.

13. The semiconductor device of claim 11, wherein
the trench and the first and second lower patterns extend longitudinally in a first direction, and
in the first direction, a width of the trench is smaller than widths of the first and second lower patterns.

14. The semiconductor device of claim 11, further comprising:
a plurality of first sheet patterns stacked on the first lower pattern and spaced apart from each other;
a plurality of second sheet patterns stacked on the second lower pattern and spaced apart from each other; and
a gate electrode surrounding the plurality of first sheet patterns and the plurality of second sheet patterns, on the first and second lower patterns.

15. The semiconductor device of claim 11, wherein at least part of an upper surface of the first lower pattern and at least part of an upper surface of the second lower pattern are inclined relative to an upper surface of the substrate.

16. The semiconductor device of claim 15, wherein relative to a vertical direction,
the at least part of the upper surface of the first lower pattern has a positive inclination, and
the at least part of the upper surface of the second lower pattern has a negative inclination.

17. A method for fabricating a semiconductor device, comprising:
forming a first trench in a substrate;
forming a stacked pattern on the substrate and along the first trench, the stacked pattern including a plurality of active layers and a plurality of sacrificial layers that are alternately stacked in a vertical direction, an upper surface of the stacked pattern including a recess overlapping the first trench in the vertical direction;
forming a stopper film on the stacked pattern;
forming a mask pattern including an opening on the stopper film, the opening overlapping the recess in the vertical direction;
etching the stopper film, the stacked pattern, and the substrate using the mask pattern to remove the recess and to form a second trench; and
forming an element isolation film filling the second trench.

18. The method of claim 17, wherein the first trench includes a plurality of first trenches and the recess includes a plurality of recesses.

19. The method of claim 17, wherein a bottom surface of the second trench has a step difference.

20. The method of claim 17, wherein an upper surface of the substrate on a sidewall of the second trench includes a portion inclined relative to the vertical direction.
